(19) United States
(12) Patent Application Publication
(10) Pub. No.: US 2003/0111713 A1
(43) Pub. Date: Jun. 19, 2003

(54) Manufacturing method of tape carrier package and the system thereof

(76) Inventor: Ming-Hsiang Cheng, Kaoshiung (TW)

Correspondence Address: SEYFARTH SHAW, 55 EAST MONROE STREET, SUITE 4200, CHICAGO, IL, 60603-5803, US

(21) Appl. No.: 10/317,882

(22) Filed: Dec. 12, 2002

(30) Foreign Application Priority Data
Dec. 14, 2001 (TW) 090131080

(51) Int. Cl. H01L 23/495

(52) U.S. Cl. 257/668

(57) ABSTRACT

The invention discloses a manufacturing method of tape carrier package (TCP) and the system thereof, which uses an insulating resin material to attain the object of circuit protection. The resin material will be hardened after irradiating with specific light. By utilizing such characteristics of the chemical reaction, the duration necessary for curing process can be reduced greatly and the process flow in the conventional technology can be simplified.

### BACKGROUND OF THE INVENTION

1. Field of the Invention

The invention discloses a manufacturing method of tape carrier package and the system thereof, especially relates to a manufacturing method and the system thereof, which may efficiently complete the curing process of resin layer for protecting the product.

2. Description of the Related Art

Tape carrier package is a packaging method extensively applied in the driver device of LCD (liquid crystal display) panel. Referring to FIG. 1, pluralities of chip 11 are mounted on the whole roll of flexible tape carrier 12 in sequent. Furthermore, the type of mass production is loaded with the whole roll of tape carrier 12, and the final products are also unloaded in the same reel-to-reel way to become a roll of tape carrier 12 chips mounted. The main structure of the tape carrier package includes a chip 11 with gold bump 13, an carrier film 121 and a metal layer comprising inner lead bond (ILB) area 122 and outer lead bond (OLB) area 123. Each inner lead of ILB area 122 and the corresponding gold bump 13 on the chip 11 is well welded by the method of thermo-compression. Generally, in order to ensure that the interconnections within the inner leads and the chip are not influenced by the external environment and protect against the damage caused by the external force due to the transfers during the succeeding processes. The gap between the chip 11 and the ILB area 122 should be dispensed with insulating resin layer 14, and then the insulating resin layer 14 is thermally hardened by a curing oven to get the best protection for the product.

The conventional manufacturing method of the tape carrier package is as FIG. 2. In step 21, the wafer with gold bumps is first diced into a plurality of individual chips. In step 22, the gold bumps on the chip and the Ni—Au electroplating layer of inner leads are welded together in high temperature and compressing stress by thermo-compression bonding equipment. Because the total thickness of inner lead is extremely thin (around 18 μm/25 μm/35 μm) and with fine width (around 100 μm), the interconnection part of which is easily to be damaged by wresting in the succeeding process transfers. In step 23, the insulating resin layer 14 (or referred as liquid encapsulation) is used to protect the fine structure of the ILB area 122. In step 24, the pre-cure process is used to harden the surface of sticky liquid resin layer to keep it with the fixed profile. The pre-cure process is conducted in a sealed chamber, and the tape carrier is passed through the space in temperature of 120° C. by way of continuous transportation and dwelling in the high temperature chamber for about 20 minutes. The products after pre-cure process are rolled on a reel in sequence with a tape carrier unloading mechanism.

Because the resin layer of the products through pre-curing is not completely hardened, the damages caused by the environment factors (moisture, oxidation, etc.) to the product cannot be prevented for lack of the true inner protection. Thus, a post-cure process must be proceeded after pre-curing, as in Step 25, which is used to completely harden the resin layer of the product till the resin layer has the cross link reaction of the chemical molecules chains at nearly 100%. The execution of the post-cure is to put the reel of the whole rolled tape carrier into the oven, and take it out after curing for 60 minutes under 120° C. Because the step of the post-cure and pre-cure takes about 80 minutes in total, and if the resin layer hardening process is completed only through transportation manner incorporated in pre-curing process, essentially a oven-with a very long tunnel for pre-curing process is needed. Obviously, it does not comply with the space utilization efficiency of the clean room. Therefore, the conventional technology needs to adopt two-stage curing process.

In order to easily identify the series number, production data (manufacturing date and wafer batch lot number, etc.) and manufacturer logo of each product, it is necessary to have the top marking of the relevant information on the surface of every product, such as in step 26. The top marking is printed on the surface of the product with specific characters or patterns in ink using transfer-printing method. The products with top marking can be packed for shipping after the verification of the final QC staffs, such as in step 27. As the described, because the prior art needs to take a large amount of time in hardening resin process, which obviously is not complied with the manufacturing efficiency and the cycle time requirement of the electrical marketing. Therefore, how to effectively improve is an urgent issue.

### SUMMARY OF THE INVENTION

The first object of the invention is to provide a manufacturing method for rapidly completing the hardening resin process for protecting the products, which takes about 0.6% of the time in comparison with the conventional technology.

The second object of the invention is to provide a manufacturing method for saving the purchasing cost of the oven, comparing with the cost of the oven for the conventional technology about NT$400,000˜500,000. The invention only takes 10% of the amount on purchasing hardening resin equipment.

The third object of the invention is to provide a manufacturing method with simplified process flow, which simplifies the original two-stage curing process to complete the dispensing and hardening operation at one stage.

The fourth object of the invention is to provide a tape carrier packaging system, which can save the space of clean room.

To achieve the above objects, the invention discloses a manufacturing method and the system thereof, which can rapidly complete the hardening process of the protective resin layer for the products, which is applied in the tape carrier package production. The conventional technology adopts the thermoset material as the material of protective resin layer, so that it needs the curing equipment and a certain heating time to complete the chemical reaction mechanism of the material. The invention uses a resin material, which will be hardened after irradiating with ultra-violet (UV) rays. The resin material accepts the energy transported by the light wave to excite the polymer to conduct polymerization, generally referred as UV resin in brief.

The tape carrier package of the invention still needs to have the process of wafer dicing and inner lead bond. During dispensing resin process, the UV resin is used as the protective resin layer at the inner lead bond area of the tape carrier and the chip. The product dispensed with UV resin should pass through an UV irradiation area to harden the UV resin layer. The product with fully hardened resin layer may directly proceed with the top marking process and the final packing for shipping step.

### BRIEF DESCRIPTION OF THE DRAWINGS

The invention will be described according to the appended drawings, in which:

FIG. 1 is the structural schematic diagram of the tape carrier package;

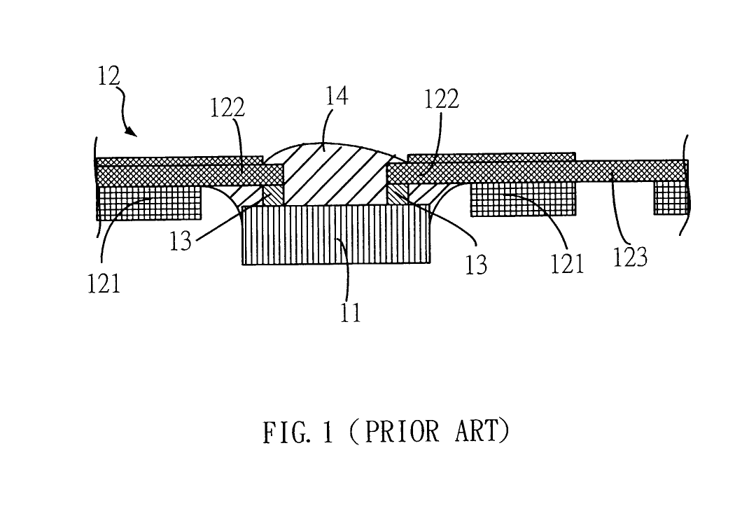

FIG. 2 is the process flow chart of a prior art of the tape carrier package;

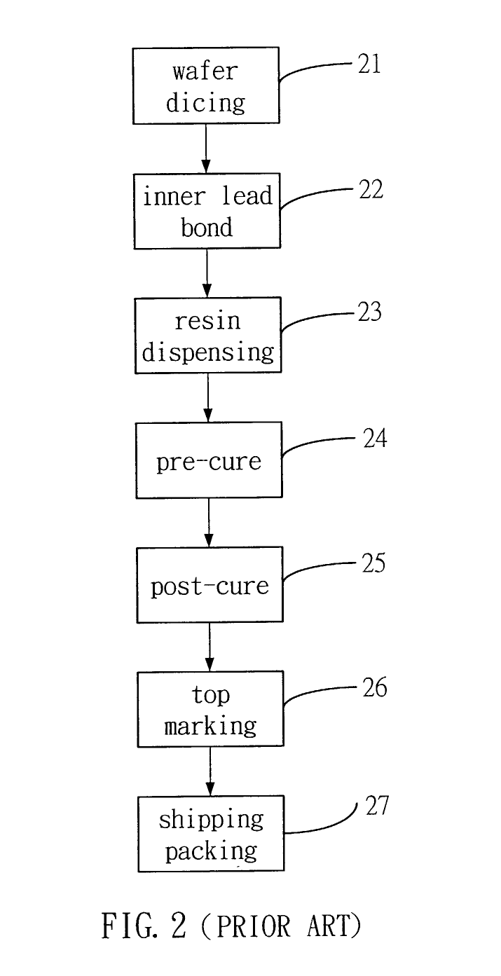

FIG. 3 is the process flow chart of the tape carrier package in accordance with the invention; and

FIG. 4 is the schematic diagram of the tape carrier package system in accordance with one preferred embodiment of the invention.

### PREFERRED EMBODIMENT OF THE PRESENT INVENTION

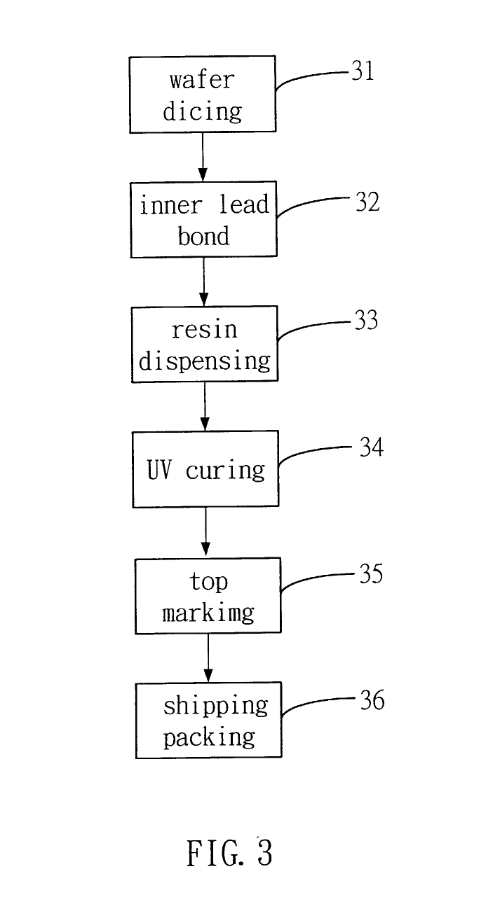

FIG. 3 is the process flow chart of the tape carrier package in accordance with the invention. In step 31, the chips on the wafer are diced into independent units. In step 32, using thermo-compression bonding equipment to apply the melting effect of temperature and pressure on each gold bump on the chip to be respectively welded with the gold electroplating layer on the inner lead. In step 33, protecting the ILB area dispenses with the UV resin. In step 34, curing the sticky UV resin layer on tape carrier with UV rays, and the UV resin will conduct with polymerization to be hardened after sufficiently irradiating with UV rays in specific wavelength. The product with hardened resin layer can proceed with top marking directly, such as in step 35; the identifiable logo and characters will be printed on the surface. At last, the product will be put into an anti-electrostatic bag and carton to complete the package for shipping operation, such as in step 36.

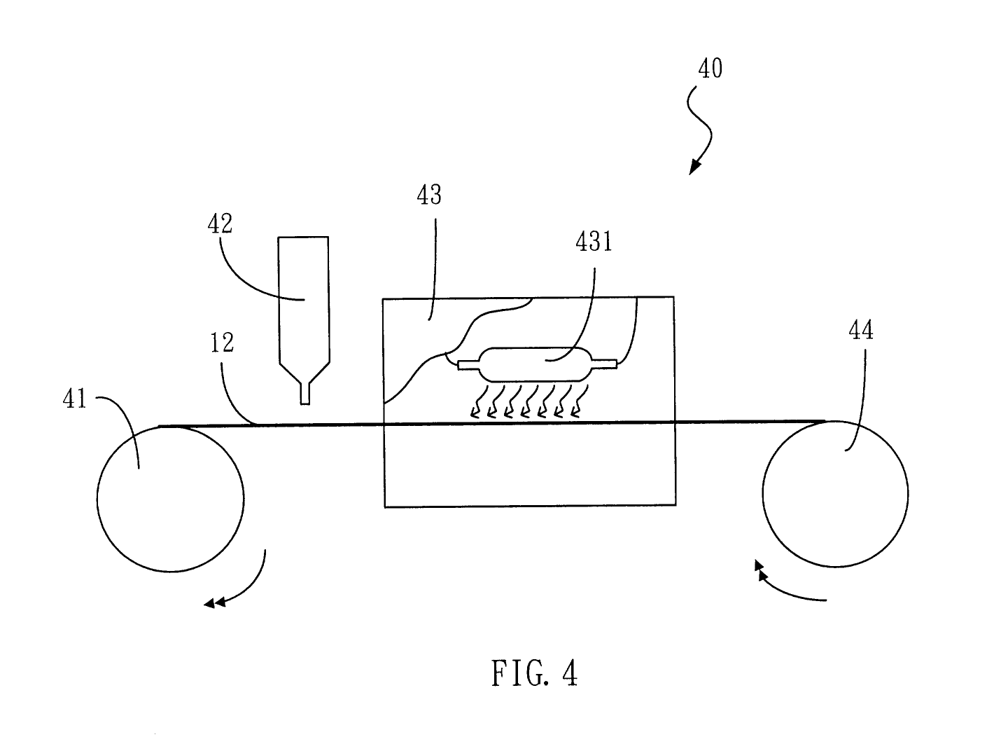

FIG. 4 is the illustrative diagram of the tape carrier package system 40 in accordance with one preferred embodiment of the invention. From inner lead bond process to UV resin dispensing process, there is a material-feeding mechanism 41 to draw out the whole roll of tape carrier 12 to be positioned in the resin-dispensing equipment 42. The resin-dispensing equipment 42 dispenses with UV resin on each joint of the inner lead and the gold bump in the product. The UV resin may select from the product manufactured by LOCTITE Co. or DOW CORNING Co., such as the Model type 366 of the light cure series, manufactured by LOCTITE, which is the more suitable resin material in the series product due to the acrylic acid group therein.

The product just after dispensing with UV resin needs to be passed through sealed UV curing equipment 43 because the resin layer is still in a sticky liquid state. In the UV curing equipment 43, there is an UV irradiation lamp 431 (e.g. a mercury arc lamp), which may irradiate UV rays with specific dosage and wavelength according to the requirement of resin material so as to completely harden the UV resin layer. Generally, the low-intensity irradiation UV resin will cure when exposed to roughly 30˜50 mW/cm2, while the high-intensity irradiation UV resin require intensities in the 80˜100 mW/cm2 region and above. After irradiating with UV irradiation lamp 431 for 30 seconds, the resin layer of the product is completely hardened. In other words, the tape carrier passing through the space of UV curing equipment 43 can achieve the object for hardening the resin layer without such a long time as the conventional method has. Then, the product passed through UV curing equipment 43 is rolled on a reel by a material-collecting mechanism 44. Thus the processes of the invention are completed.

The above-described embodiments of the present invention are intended to be illustrated only. Numerous alternative embodiments may be devised by persons skilled in the art without departing from the scope of the following claims.

What is claimed is:

1. A manufacturing method of a tape carrier package, comprising the steps of:
welding bumps on a chip and inner leads of said tape carrier by thermo-compression;
covering said welded region with a UV resin;
irradiating said UV resin with UV rays for hardening said UV resin; and
rolling said tape carrier on a reel.

2. A tape carrier package system, including:
a material-feeding mechanism;
a resin-dispensing equipment;
a curing equipment; and
a material-collecting mechanism;
characterized in that said resin-dispensing equipment utilizes a UV resin and said curing equipment hardens said UV resin by an irradiation of UV rays.

3. The tape carrier package system in claim 2, wherein said curing equipment uses a lamp irradiating UV rays.

4. The tape carrier package system in claim 3, wherein said lamp irradiating UV rays includes a mercury arc bulb.

5. The tape carrier package system in claim 2, wherein said curing equipment has a sealed box for preventing said UV rays from exposing to operators.
